(19) United States
(12) Patent Application Publication
(10) Pub. No.: US 2023/0200193 A1
(43) Pub. Date: Jun. 22, 2023

(54) ELECTROLUMINESCENCE DISPLAY

(71) Applicant: LG DISPLAY CO., LTD., SEOUL (KR)

(72) Inventors: Donghun KANG, Paju-si (KR); WooJung BYUN, Paju-si (KR); Jaewon HWANG, Paju-si (KR); Kwangjin BAE, Paju-si (KR)

(73) Assignee: LG DISPLAY CO., LTD., SEOUL (KR)

(21) Appl. No.: 17/896,528

(22) Filed: Aug. 26, 2022

(30) Foreign Application Priority Data
Dec. 21, 2021 (KR) 10-2021-0183983

(51) Int. Cl. H01L 27/32; G09G 3/3233; H01L 51/56

(52) U.S. Cl. CPC H01L 27/3223; G09G 3/3233; H01L 27/3258; H01L 27/3272; H01L 27/3276; H01L 51/56; G09G 2330/08; G09G 2300/0842; H01L 2251/568; H01L 2251/533

(57) ABSTRACT

An electroluminescence display includes a first line disposed on a substrate, a buffer layer covering the first line on the substrate, a repair branch line disposed on the buffer layer and crossing over the first line from one side to other side, a gate insulating layer covering the repair branch line on the substrate; and a second line disposed on the gate insulating layer and crossing over the first line, wherein the repair branch line includes a first end disposed outside of the one side and a second end disposed outside of the other side, the second line includes a upper branch line being apart from the repair branch line, the first end of the repair branch line overlaps with a first area of the upper branch line, and the second end of the repair branch line overlaps with a second area of the upper branch line.

### CROSS-REFERENCE TO RELATED APPLICATION

This application claims the priority of Korean Patent Application No. 10-2021-0183983 filed on Dec. 21, 2021, which is hereby incorporated by reference in its entirety.

### BACKGROUND

### Field of the Disclosure

The present disclosure relates to an electroluminescence display having a repair structure for recovering an electrical connection when a signal line such as a gate line is disconnected or broken. Especially, the present disclosure relates to a bottom emission type electroluminescence display having a repair structure for recovering an electrical connection when a disconnection or breakage occurs in a gate line at a cross structure of a data line and a gate line overlapping with an insulating layer therebetween.

### Description of the Background

Recently, various type of display such as the cathode ray tubes (CRTs), the liquid crystal displays (LCDs), the plasma display panels (PDPs) and the electroluminescence displays have been developed. These various types of displays are used to display image data of various products such as computer, mobile phones, bank deposit and withdrawal devices (ATMs), and vehicle navigation systems according to their unique characteristics and purposes.

In particular, the electroluminescence display which is a self-luminous display, has an excellent optical performance such as a viewing angle and color realization degree, so that its application field is gradually widening and is receiving attention as an image display device. With these advantages, it is attracting attention as the most suitable display device for implementing 8K ultra high resolution displays beyond 4K resolution. As the resolution is increased, the size of the pixel becomes smaller, and the width of the lines that transmit electrical signals also becomes narrower.

For the ultra-high resolution electroluminescence display such as mentioned above, as the number of structural portions in which narrow lines are crossing each other with an insulating layer there-between increases, the possibility of the disconnection at the upper line crossing over the lower line disposed on the top of the insulating layer at the intersection of the lines increases. Therefore, there is a need for structural features that can be easily repaired and/or restored for the ultra-high resolution electroluminescence display device when a disconnection occurs at the intersection area.

### SUMMARY

Accordingly, the present disclosure, as for solving the problems described above, is to provide an electroluminescence display, in implementing the ultra-high resolution, having a repair structure capable of repairing a disconnection or break when the disconnection or the break occurs at an intersecting (or crossing) structure in which a narrow-width line crosses another line with an insulating layer interposed there-between.

The present disclosure is also to provide an electroluminescence display having a self-repair structure without conducting a specific repairing process even when a disconnection or a break occurs at the upper line in a crossing (or intersecting) structure in which a narrow upper line crosses another line disposed below the narrow upper line with an insulating layer interposed there-between.

In an aspect of the present disclosure, an electroluminescence display includes a first line disposed on a substrate; a buffer layer covering the first line on the substrate; a repair branch line disposed on the buffer layer and crossing over the first line from one side to other side of the first line; a gate insulating layer covering the repair branch line on the substrate; and a second line disposed on the gate insulating layer and crossing over the first line, wherein the repair branch line includes: a first end disposed outside of the one side of the first line and a second end disposed outside of the other side of the first line, wherein the second line includes a upper branch line being apart from the repair branch line and above the repair branch line, wherein the first end of the repair branch line overlaps with a first area of the upper branch line, and wherein the second end of the repair branch line overlaps with a second area of the upper branch line.

In one aspect, the first end of the repair branch line is connected to the first area, and the second end of the upper branch line is welded with the second area of the upper branch line by welding, when the upper branch line has a disconnection.

In one aspect, the gate insulating layer includes a first contact hole exposing the first end of the repair branch line, and the first area of the upper branch line contacts to the first end of the repair branch line via the first contact hole.

In one aspect, the second end of the repair branch line is connected to the second area of the upper branch line by welding, when the upper branch line has a disconnection.

In one aspect, the gate insulating layer further includes a second contact hole exposing the second end of the repair branch line, and the second area of the upper branch line contacts the second end of the repair branch line via the second contact hole.

In one aspect, the upper branch line and the repair branch line form a hexagonal shape in a planar structure, the first area of the upper branch line is overlapped with the first end of the repair branch line at a first vertex of the hexagonal shape, and the second area of the upper branch line is overlapped with the second end of the repair branch line at a second vertex of the hexagonal shape opposed the first vertex.

In one aspect, the upper branch line extends in a straight line with the second line, the upper branch line and the repair branch line form a rectangular shape in a planar structure, the first area of the upper branch line is overlapped with the first end of the repair branch line at a first vertex of the rectangular shape, and the second area of the upper branch line is overlapped with the second end of the repair branch line at a second vertex of the rectangular shape opposed the first vertex.

In one aspect, the upper branch line and the repair branch line form a circular shape in a planar structure, the upper branch line has a convex semi-circular shape, the repair branch line has a concave semi-circular shape, the first area of the upper branch line is overlapped with the first end of the repair branch line at a first intersection where the convex semi-circular shape and the concave semi-circular shape intersect, and the second area of the upper branch line is overlapped with the second end of the repair branch line at a second intersection where the convex semi-circular shape and the concave semi-circular shape intersect.

In one aspect, the first line includes a data line and a driving current line, the second line includes a gate line, and the electroluminescence display further comprises: a switching thin film transistor connected to the gate line and the data line; a driving thin film transistor connected to the switching thin film transistor and the driving current line; a planarization layer covering the switching thin film transistor and the driving thin film transistor above the substrate; and a light emitting element on the planarization layer and connected to the driving thin film transistor.

A method for manufacturing an electroluminescence display according to this disclosure comprising steps of: forming a first line on a substrate; depositing a buffer layer covering the first line on the substrate; forming a repair branch line on the buffer layer and crossing over the first line from one side to other side; depositing a gate insulating layer covering the repair branch line on the substrate; and forming a second line crossing over the first line on the gate insulating layer. The repair branch line includes: a first end disposed outside of the one side of the first line and a second end disposed outside of the other side of the first line. The second line includes a upper branch line being apart from the repair branch line and above the repair branch line. The first end of the repair branch line overlaps with a first area of the upper branch line, and the second end of the repair branch line overlaps with a second area of the upper branch line.

In one aspect, the method further comprises steps of: inspecting an electrical disconnection at the upper branch line; and repairing the electrical disconnection by welding the first end of the repair branch line with the first area of the upper branch line, and welding the second end of the repair branch line with the second area of the upper branch line, when the upper branch line has the electrical disconnection.

In one aspect, the step of depositing the gate insulating layer includes forming a first contact hole exposing the first end of the repair branch line. In the step of the second line, the first area of the upper branch line contacts the first end of the repair branch line via the first contact hole.

In one aspect, the method further comprises steps of: inspecting an electrical disconnection at the upper branch line; and repairing the electrical disconnection by welding the second end of the repair branch line with the second area of the upper branch line, when the upper branch line has the electrical disconnection.

In one aspect, the step of depositing the gate insulating layer further includes forming a second contact hole exposing the second end of the repair branch line. In the step of the second line, the second area of the upper branch line contacts the second end of the repair branch line via the second contact hole.

The electroluminescence display according to the present disclosure comprises a repair structure. By the use of the repair structure, any broken or disconnected line can be restored by the laser process in the case of a break at the upper line at the crossing structure in which the upper line having a narrow width crosses over the lower line disposed below the upper line with an insulating layer interposed there-between. In addition, the present disclosure may provide an electroluminescence display device in which self-repair is accomplished due to the repair line provided below the upper line and always connected to the upper line without performing a repair process, even when the upper line is disconnected. Therefore, the present disclosure may have an advantage that any disconnection of the lines may be easily recovered, when manufacturing the ultra-high resolution electroluminescence display. According to the present disclosure, in manufacturing an ultra-high resolution electroluminescence display, the productivity may be improved by reducing the defect rate due to the disconnection of lines.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain the principle of the disclosure.

In the drawings:

FIG. 1 is a plan view illustrating a schematic structure of an electroluminescence display according to the present disclosure;

FIG. 2 is a circuit diagram illustrating a structure of one pixel according to the present disclosure;

FIG. 3 is a plan view illustrating a structure of the pixels disposed in the electroluminescence display according to the present disclosure;

FIG. 4 is a cross-sectional view along cutting line I-I′ in FIG. 3, for illustrating the structure of the electroluminescence display according to the present disclosure;

FIG. 5 is an enlarged plan view illustrating a structure of the gate line intersecting the data line in the electroluminescence display according to a first aspect of the present disclosure.

FIG. 6A is an enlarged cross-sectional view along cutting line II-II′ in FIG. 5, for illustrating a structure of the gate line intersecting the data line in the electroluminescence display according to the first aspect of the present disclosure;

FIG. 6B is an enlarged cross-sectional view along cutting line III-III′ in FIG. 5, for illustrating a structure of the repair gate line intersecting the data line in the electroluminescence display according to the first aspect of the present disclosure;

FIG. 7 is an enlarged cross-sectional view along cutting line II-II′ in FIG. 5, for illustrating a structure of the gate line intersecting the data line in the electroluminescence display according to a second aspect of the present disclosure;

FIG. 8 is an enlarged cross-sectional view along cutting line II-II′ in FIG. 5, for illustrating a structure of the gate line intersecting the data line in the electroluminescence display according to a third aspect of the present disclosure;

FIG. 9 is an enlarged plan view illustrating a structure of the gate line intersecting the data line in the electroluminescence display according to a fourth aspect of the present disclosure and

FIG. 10 is an enlarged plan view illustrating a structure of the gate line intersecting the data line in the electroluminescence display according to a fifth aspect of the present disclosure.

### DETAILED DESCRIPTION OF THE DISCLOSURE

Reference will now be made in detail to the exemplary aspects of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these example aspects are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example aspects of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function or configuration may be omitted.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various aspects of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “under” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts. Since a scale of each of elements shown in the accompanying drawings may be different from an actual scale for convenience of description, the present disclosure is not limited to the scale shown in the drawings.

FIG. 1 is a diagram illustrating a schematic structure of an electroluminescence display according to the present disclosure. In FIG. 1, the X-axis may be parallel to the extending direction of the scan line (also referred to the gate line), the Y-axis may be parallel to the extending direction of the data line, and the Z-axis may represent the thickness direction of the display.

Referring to FIG. 1, the electroluminescence display includes a substrate 110, a gate (or scan) driver 210, a data pad portion 310, a source driving IC (Integrated Circuit) 410, a flexible film 430, a circuit board 450, and a timing controller 500.

The substrate 110 may include an electrical insulating material or a flexible material. The substrate 110 may be made of a glass, a metal or a plastic, but it is not limited thereto. When the electroluminescence display is a flexible display, the substrate 110 may be made of a flexible material such as plastic. For example, the substrate 110 may include a transparent polyimide material.

The substrate 110 may include a display area DA and a non-display area NDA. The display area DA, which is an area for representing the video images, may be defined as the majority middle area of the substrate 110, but it is not limited thereto. In the display area DA, a plurality of scan lines (or gate lines), a plurality of data lines and a plurality of pixels may be formed or disposed. Each of pixels may include a plurality of sub pixels. Each of sub pixels includes the scan line and the data line, respectively.

The non-display area NDA, which is an area not representing the video images, may be defined at the circumference areas of the substrate 110 surrounding all or some of the display area DA. In the non-display area NDA, the gate driver 210 and the data pad portion 310 may be formed or disposed.

The gate driver 210 may supply the scan (or gate) signals to the scan lines according to the gate control signal received from the timing controller 500. The gate driver 210 may be formed at the non-display area NDA which is located at any one outside of the display area DA on the substrate 110, as a GIP (Gate driver In Panel) type. GIP type means that the gate driver 210 is directly formed on the substrate 110.

The data pad portion 310 may supply the data signals to the data line according to the data control signal received from the timing controller 500. The data pad portion 310 may be made as a driver chip and mounted on the flexible film 430. Further, the flexible film 430 may be attached at the non-display area NDA which is located at any one outside the display area DA on the substrate 110, as a TAB (Tape Automated Bonding) type.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible film 430 as a COF (Chip On Film) or COP (Chip On Plastic) type.

The flexible film 430 may include a plurality of first link lines connecting the data pad portion 310 to the source driving IC 410, and a plurality of second link lines connecting the data pad portion 310 to the circuit board 450. The flexible film 430 may be attached on the data pad portion 310 using an anisotropic conducting film, so that the data pad portion 310 may be connected to the first link lines of the flexible film 430.

The circuit board 450 may be attached to the flexible film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

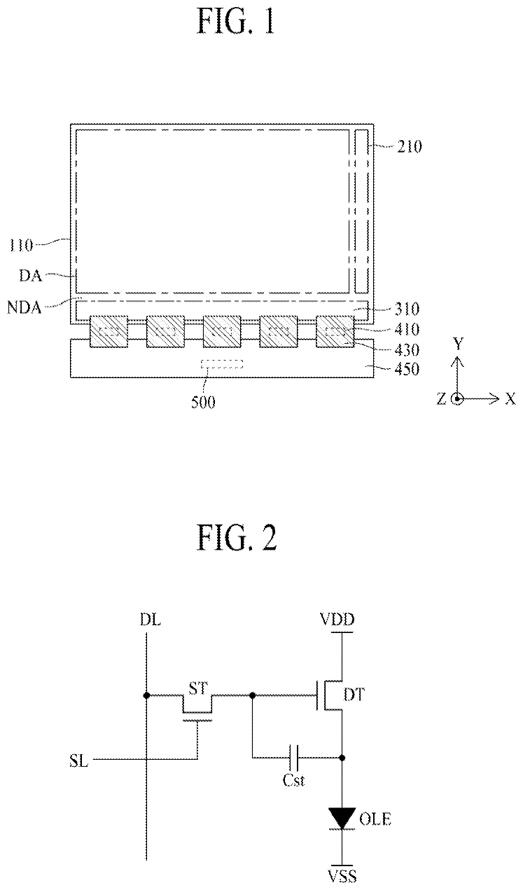

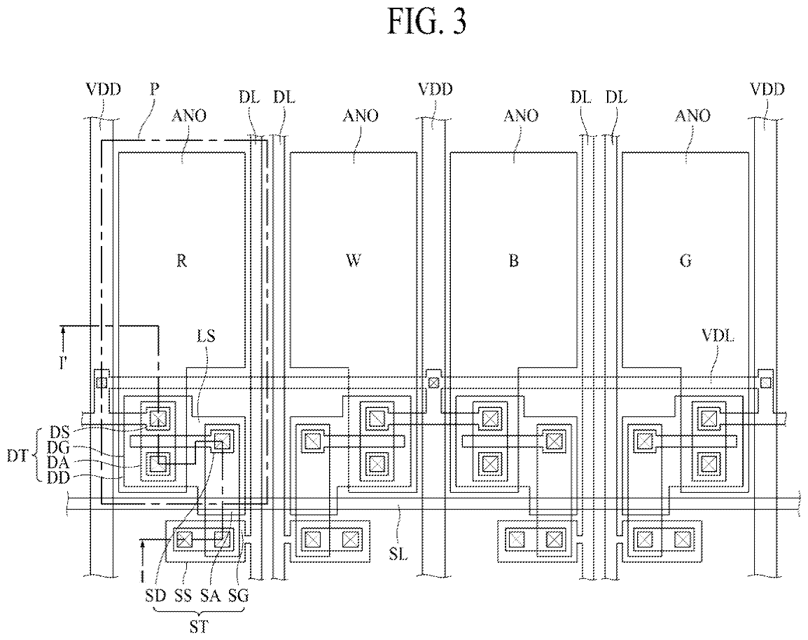

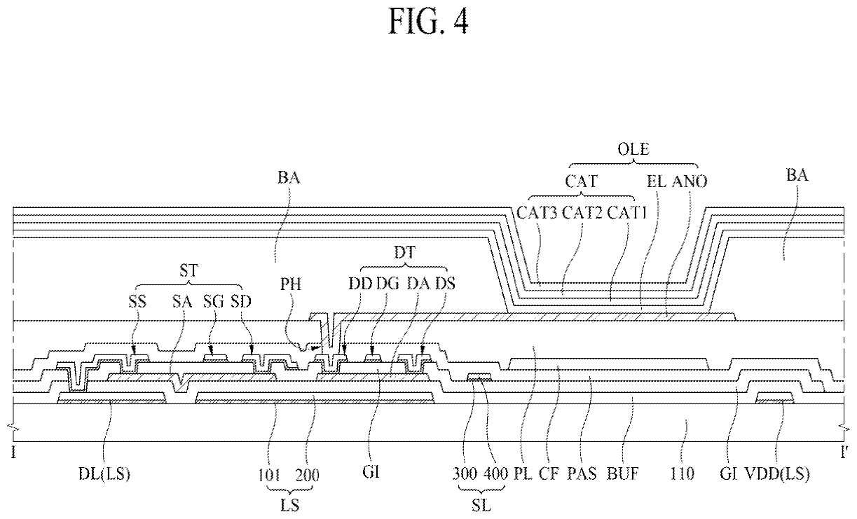

Hereinafter, referring to FIGS. 2 to 4, detailed structure of an electroluminescence display according to the present disclosure will be explained. FIG. 2 is a circuit diagram illustrating a structure of one pixel according to the present disclosure. FIG. 3 is a plan view illustrating a structure of the pixels according to the present disclosure. FIG. 4 is a cross-sectional view along cutting line I-I′ in FIG. 3, for illustrating the structure of the electroluminescence display according to the present disclosure. Referring FIGS. 2 to 4, we may explain the example of the present disclosure using an organic light emitting display, one aspect of the luminescence display device (or ‘apparatus’).

Referring to FIGS. 2 to 4, one-pixel P of the light emitting display may be defined by a scan line SL, a data line DL and a driving current line VDD. One pixel of the light emitting display may include a switching thin film transistor ST, a driving thin film transistor DT, a light emitting diode OLE and a storage capacitance Cst. The driving current line VDD may be supplied with a high-level voltage for driving the light emitting diode OLE.

For example, the switching thin film transistor ST may be disposed at the portion where the scan line SL and the data line DL is crossing. The switching thin film transistor ST may include a switching gate electrode SG, a switching source electrode SS and a switching drain electrode SD. The switching gate electrode SG may be connected to the scan line SL. The switching source electrode SS may be connected to the data line DL and the switching drain electrode SD may be connected to the driving thin film transistor DT. By supplying the data signal to the driving thin film transistor DT, the switching thin film transistor ST may play a role of selecting a pixel which would be driven.

The driving thin film transistor DT may play a role of driving the light emitting diode OLE of the selected pixel by the switching thin film transistor ST. The driving thin film transistor DT may include a driving gate electrode DG, a driving source electrode DS and a driving drain electrode DD. The driving gate electrode DG may be connected to the switching drain electrode SD of the switching thin film transistor ST. For example, the driving gate electrode DG may be connected to the witching drain electrode SD via the drain contact hole DH penetrating the gate insulating layer GI covering the driving gate electrode DG. The driving source electrode DS may be connected to the driving current line VDD, and the driving drain electrode DD may be connected to an anode electrode ANO of the light emitting diode OLE. A storage capacitance Cst may be disposed between the driving gate electrode DG of the driving thin film transistor DT and the anode electrode ANO of the light emitting diode OLE.

The driving thin film transistor DT may be disposed between the driving current line VDD and the light emitting diode OLE. The driving thin film transistor DT may control the amount of electric currents flowing to the light emitting diode OLE from the driving current line VDD according to the voltage level of the driving gate electrode DG connected to the switching drain electrode SD of the switching thin film transistor ST.

The light emitting diode OLE may include an anode electrode ANO, an emission layer EL and a cathode electrode CAT. The light emitting diode OLE may emit the light according to the amount of the electric current controlled by the driving thin film transistor DT. In other word, the light emitting diode OLE may be driven by the voltage differences between the low-level voltage and the high-level voltage controlled by the driving thin film transistor DT.

Referring to FIG. 4 mainly, a cross-sectional structure of the electroluminescence display according to the present disclosure will be explained. A light shielding layer LS may be disposed on the substrate 110. A part of the light shielding layer LS may be used as the data line DL and the driving current line VDD. Further, the light shielding layer LS may be formed as being an island shape as overlapping with the semiconductor layers SA and DA and being separated from the data line DL and the driving current line VDD with a predetermined distance. The portions of the light shielding layer LS not included into the signal lines may be used to prevent the properties of the semiconductor layers SA and DA from being deteriorated by blocking the external light incident into the semiconductor layers SA and DA. Therefore, the light shielding layer LS may be disposed to overlap the channel areas in the semiconductor layers SA and DA, wherein the channel area are overlapped with the gate electrodes SG and DG. In addition, the light shielding layer LS may be disposed so as to overlap some areas of the source-drain electrodes SS, SD, DS and DD in contact with the semiconductor layers SA and DA.

A buffer layer BUF may be disposed on the light shielding layer LS and may cover a surface of the substrate 110 exposed by the light shielding layer LS. The switching semiconductor layer SA and the driving semiconductor layer DA may be formed on the buffer layer BUF. In particular, the channel areas of the semiconductor layers SA and DA may be disposed as being overlapped with the light shielding layer LS.

A gate insulating layer GI may be stacked above the surface of the substrate 110 having the semiconductor layers SA and DA. On the gate insulating layer GI, a switching gate electrode SG overlapped with the switching semiconductor layer SA and a driving gate electrode DG overlapped with the driving semiconductor layer DA are formed. A switching source electrode SS may be formed at one side of the switching gate electrode SG, and the switching source electrode SS may be formed as being apart from the switching gate electrode SG and as contacting one side of the switching semiconductor layer SA. A switching drain electrode SD may be formed at the other side of the switching gate electrode SG, and the switching drain electrode SD may be formed as being apart from the switching gate electrode SG and as contacting the other side of the switching semiconductor layer SA. Further, a driving source electrode DS may be formed at one side of the driving gate electrode DG, and the driving source electrode DS may be formed as being apart from the driving gate electrode DG and as contacting one side of the driving semiconductor layer DA. A driving drain electrode DD may be formed at the other side of the driving gate electrode DG, and the driving drain electrode DD may be formed as being apart from the driving gate electrode DG and as contacting the other side of the driving semiconductor layer DA.

The gate electrodes SG and DG and the source-drain electrodes SS, SD, DS and DD may be formed as the layer located at the same leveled, but they are separated from each other. The switching source electrode SS may be connected to the data line DL formed of some portions of the light shielding layer LS via a contact hole penetrating the gate insulating layer GI and the buffer layer BUF. Further, the driving source electrode DS may be connected to the driving current line VDD formed of some portions of the light shielding layer LS via another contact hole penetrating the gate insulating layer GI and the buffer layer BUF. Accordingly, the switching thin film transistor ST and the driving thin film transistor DT are formed on the substrate 110.

A passivation layer PAS may be disposed on the substrate 110 having the thin film transistors ST and DT. The passivation layer PAS may be made of an inorganic material such as silicon nitride or silicon oxide. A color filter CF may be disposed on the passivation layer PAS. The color filter CF is the element for representing color allocated to each of pixels. For an example, the color filter CF may have the size and the shape corresponding to one of the pixel area. For another example, the color filter CF may have a size slightly larger than that of the light emitting diode OLE which may be formed later and may be disposed to overlap the light emitting diode OLE.

A planarization layer PL may be disposed on the color filter CF. The planarization layer PL may be a film layer for flattening the non-uniform surface of the substrate 110 on which the thin film transistors ST and DT are formed. In order to make the height difference uniform, the planarization layer PL may be formed of an organic material. The passivation layer PAS and the planarization layer PL may have a pixel contact hole PH for exposing some portions of the driving drain electrode DD of the driving thin film transistor DT.

The anode electrode ANO may be formed on the planarization layer PL covering the thin film transistors ST and DT. The anode electrode ANO may be connected to the driving drain electrode DD of the driving thin film transistor DT through a pixel contact hole PH formed at the planarization layer PL. The anode electrode ANO may have various structures and different materials according to the emission type of the organic light emitting diode OLE. For an example, for the bottom emission type in which the light may be provided by the emission layer EL toward the substrate 110, the anode electrode ANO may be made of a transparent conductive material. For another example, for the top emission type in which the light may be provided in a direction away from the substrate 110, the anode electrode ANO may be made of metal materials having excellent light reflectance.

In the case of a large area display device such as a TV set, the cathode electrode CAT disposed on the anode electrode ANO may be formed as one layer as covering a large area. The cathode electrode CAT may maintain a uniform low voltage over a wide area. Therefore, in the case of a large-area display device, the cathode electrode CAT may be formed of an opaque metal material in order to maintain a low sheet resistance. Therefore, in the case of a large-area display device, the bottom emission type structure may be formed. For the bottom emission type, the anode electrode ANO may be made of a transparent conductive material. For example, the anode electrode ANO may include oxide conductive materials such as indium-zin-oxide (IZO) or indium-tin-oxide (ITO).

A bank BA may be formed on the anode electrode ANO. The bank BA may cover the circumference areas of the anode electrode ANO and may expose most of middle areas of the anode electrode ANO, so the bank BA may define the emission area.

An emission layer EL may be deposited on the anode electrode ANO and the bank BA. The emission layer EL may be deposited over the whole surface of the display area DA on the substrate 110, as covering the anode electrodes ANO and banks BA. For an example, the emission layer EL may include two or more stacked emission portions for emitting white light. In detail, the emission layer EL may include a first emission layer providing a first color light and a second emission layer providing a second color light, and thus for emitting the white light by combining the first color light and the second color light.

For another example, the emission layer EL may include any one of the blue emission layer, the green emission layer and the red emission layer for providing the light having a color corresponding to the color allocated to the pixel. In addition, the light emitting diode OLE may further include functional layers for enhancing the light emitting efficiency and/or life-time of the emission layer EL.

The cathode electrode CAT may be disposed on the emission layer EL. The cathode electrode CAT may be stacked on the emission layer EL, and may be formed as being surface contact with the emission layer EL. The cathode electrode CAT may be formed as one sheet element over the whole area of the substrate 110, and may be formed as being commonly connected to entire surface of the emission layers EL disposed at all pixels. In the case of the bottom emission type, the cathode electrode CAT may include metal material having excellent light reflection ratio. For example, the cathode electrode CAT may include at least any one of silver (Ag), aluminum (Al), molybdenum (Mo), gold (Au), magnesium (Mg), calcium (Ca), copper (Cu), titanium (Ti) or barium (Ba).

The electroluminescence display explained above may have the gate line SL, gate electrodes SG and DG, the source electrodes SS and DS, and the drain electrodes SD and DD disposed at the layer which is located at the same level. Further, the data line DL, the driving current line VDD and the light shielding layer LS may be disposed at the layer which is located a the same level. For example, as shown in FIG. 4, the data line DL, the driving current line VDD and the light shielding layer LS may be firstly formed on the substrate 110. After that, the buffer layer BUF may be deposited as covering the entire surface of the substrate 110. On the buffer layer BUF, the semiconductor layers SA and DA may be formed. The gate insulating layer GI may be formed on the semiconductor layers SA and DA, and may be formed as covering the buffer layer BUF. The gate line SL, the gate electrodes SG and DG, the source electrodes SS and DS, and the drain electrodes SD and DD may be formed on the gate insulating layer GI.

Here, the gate line SL may be disposed as running along the horizontal direction of the substrate 110, while the data line DL and the driving current line VDD may be disposed as running along the vertical direction of the substrate 110. Therefore, the gate line SL and the data line DL may essentially cross each other. Since the gate line SL and the data line DL are lines that transmit different signals, the buffer layer BUF and the gate insulating layer GI are interposed there-between to prevent the lines from being shorted each other.

For example, the data line DL may be firstly formed on the substrate 110, and after that, the buffer layer BUF and the gate insulating layer GI are formed. The gate line SL may be formed on the gate insulating layer GI. As a result, the gate line SL may have a structure in which it crosses over the step formed by the data line DL. Here, the step may become very high due to the thickness of the data line DL and the thickness of the buffer layer BUF and the gate insulating layer GI stacked thereon. Due to the structure in which the gate line SL crosses over such a high step difference, there is a high possibility that the gate line SL may be disconnected. Especially, as the resolution increases and the number of pixels increases, the line width of the gate line SL may become narrower. As a result, the probability of disconnection of the gate line SL may increase much higher.

Hereinafter, referring to figures, various aspects having a repair structure capable of recovering even when a disconnection occurs at a portion where the gate line SL crosses over the data line DL will be explained.

### First Aspect

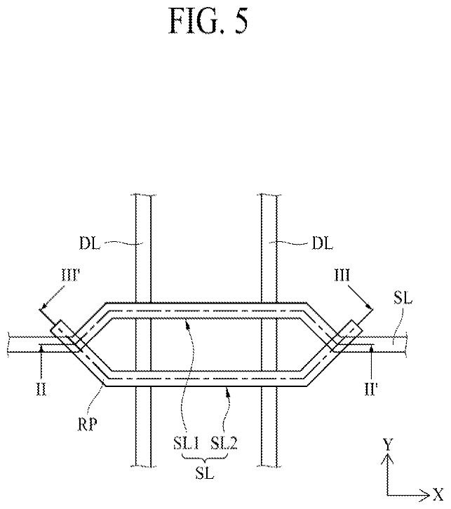

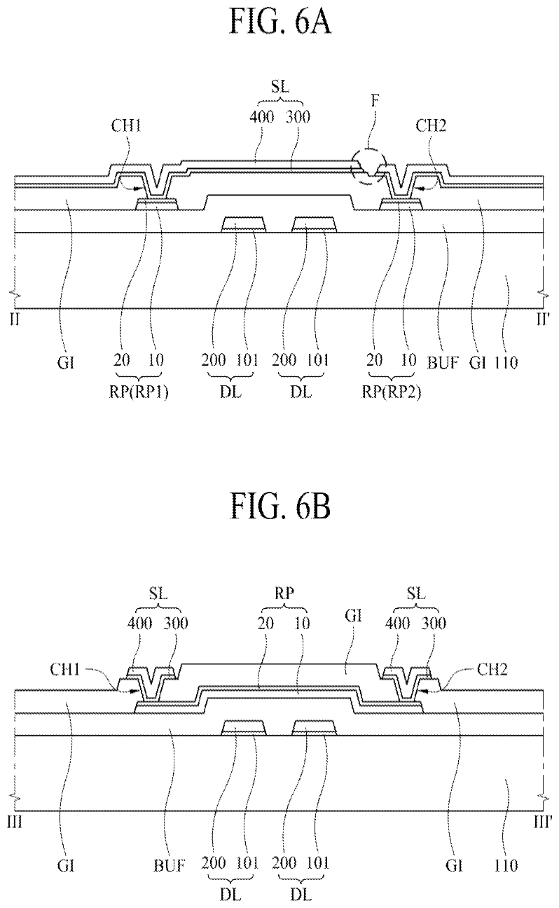

Hereinafter, referring to FIGS. 5, 6A and 6B, a first aspect of the present disclosure will be explained. FIG. 5 is an enlarged plan view illustrating a structure of the gate line intersecting the data line in the electroluminescence display according to a first aspect of the present disclosure. FIG. 6A is an enlarged cross-sectional view along cutting line II-II′ in FIG. 5, for illustrating a structure of the gate line intersecting the data line in the electroluminescence display according to the first aspect of the present disclosure. FIG. 6B is an enlarged cross-sectional view along cutting line III-III′ in FIG. 5, for illustrating a structure of the repair gate line intersecting the data line in the electroluminescence display according to the first aspect of the present disclosure.

The data line DL may have a line segment shape extending along the Y-axis direction on the XY plan of the substrate 110. A plurality of data lines DL may be arranged with a predetermined distance along the X-axis. First aspect may explain about a case in which two data lines DL may be arranged in parallel between neighboring two pixels. However, the present disclosure is not limited thereto, and one data line DL and one driving current line VDD may be arranged in parallel. The gate line SL may have a line segment shape extending along the X-axis direction on the XY plan. A plurality of gate lines GL may be arranged with a predetermined distance along the Y-axis.

Therefore, the data lines DL and the gate lines SL may be perpendicularly crossed each other. When the data line DL is firstly disposed on the substrate 110, the gate line SL may be disposed above the data line DL, and may be formed as being across the data line DL. The buffer layer BUF and the gate insulating layer GI may be disposed between the data line DL and the gate line SL. In some cases, any other insulating layer may be further disposed there-between.

Since there is a possibility that a disconnection may occur at the portion where the gate line SL crosses over the data line DL, the gate line SL may have a forked line structure at the portion overlapping the data line DL. For example, the gate line SL may be divided into two parts including an upper gate branch line SL1 and a lower gate branch line SL2.

According to the first aspect, the upper gate branch line SL1 may be a portion of the gate line SL in which the gate line SL extends as it is. While the lower gate branch line SL2 may be formed as a repair branch line RP having a short line segment shape formed at a layer different from that of the gate line SL.

As shown in the plan view of FIG. 5, the upper branch line SL1 and the lower branch line SL2 may form a hexagonal shape. The upper side and the lower side of the hexagonal shape may intersect the data line DL. The upper side may be the upper branch line SL1, and the lower side may be the lower branch line SL2. At a first vertex among the six vertices of the hexagon, which is disposed at the left end of the data line DL, the first region of the upper branch line SL1 and the first end of the lower branch line SL2 may overlap with each other. Similarly, at a second vertex which is disposed at the right end of the data line DL, the second region of the upper branch line SL1 and the second end of the lower branch line SL2 may be overlapped each other.

Referring to FIGS. 6A and 6B, the structure of the branch portions of the gate line SL will be described. FIG. 6A illustrates a cross sectional structure cutting along the center of the upper branch line SL1 in FIG. 5. FIG. 6B illustrates a cross sectional structure cutting along the center of the lower branch line SL2.

The data line DL may be disposed on the substrate 110. The data line DL may have a structure in which an oxide metal layer 101 and a metal layer 200 may be sequentially stacked for preventing the external light reflection. On the data line DL, the buffer layer BUF may be deposited as covering entire surface of the substrate 110.

The repair branch line RP may be formed on the buffer layer BUF. The repair branch line RP may be made on the same layer with the same material as the semiconductor layers SA and DA. The repair branch line RP may include the same material as the semiconductor layer SA and DA such as the silicon or germanium. It is needed that the repair branch line RP may have the conductivity level similar to that of metal material. Therefore, in the case that the repair branch line RP has a semiconductor material, n-type or p-type impurities may be implanted into the semiconductor material to ensure sufficient conductivity. Otherwise, by stacking a metal layer on a semiconductor layer, the conductivity of the repair branch line RP may have the sufficient conductivity equivalent to that of the metal material.

In this aspect, the repair branch line RP is described as having a structure in which the semiconductor layer 10 and the metal capping layer 20 are stacked sequentially. The repair branch line RP may have a line segment shape extending from one end portion of the gate line SL to the other end portion of the gate line SL. In FIG. 6A illustrating a cross-sectional view taken along cutting line II-II′, just a first end RP1 of the repair branch line RP and the second end RP2 of the repair branch line RP are depicted.

The gate insulating layer GI may be disposed on the repair branch line RP. The gate insulating layer GI may have a first contact hole CH1 exposing the first end RP1 of the repair branch line RP and a second contact hole CH2 exposing the second end RP2 of the repair branch line RP.

The gate line SL may be formed on the gate insulating layer GI. The gate line SL may have the structure in which a lower metal layer 300 and the upper metal layer 400 are sequentially stacked for preventing the external light reflection. The gat line SL may extend as one line segment shape, and may extend as being across the data line, but a portion corresponding to the repair branch line RP and crossing over the data line DL may be defined as the upper branch line SL1 that does not vertically overlap with the repair branch RP.

The upper branch line SL1 may contact the first end RP1 of the repair branch line RP via the first contact hole CH1. At the same time, the upper branch line SL1 may contact the second end RP2 of the repair branch line RP via the second contact hole CH2. In FIG. 6B illustrating a cross-sectional view taken along cutting line III-III′, one portion and the other portion of the upper branch line SL1 are depicted. As a result, the scan signal supplied through the gate line SL may be transmitted via the upper branch line SL1 and the repair branch line RP which is the lower branch line SL2.

The upper branch line SL1 may be more prone to be disconnected due to the height of the buffer layer BUF and the gate insulating layer GI stacked on the data line DL in the structure that the upper branch line SL1 crosses over the data line DL. On the other hand, since the repair branch line RP crosses over only the buffer layer BUF stacked on the data line DL, the probability of the repair branch line RP being disconnected is much lower than that of the upper branch line SL1 which is one portion of the gate line SL.

Accordingly, even when the disconnection “F” occurs in the upper branch lines SL1, the scan signal may flow along the gate line SL through the repair branch line RP. In the structure according to the first aspect, the gate line SL has a structure always connected to the repair branch line RP, so that the gate line SL can be maintained in an electrically connected state by the repair branch line RP when a disconnection “F” occurs in the upper branch line SL1. It has a self-repair structure in which the gate line SL is always electrically connected.

### Second Aspect

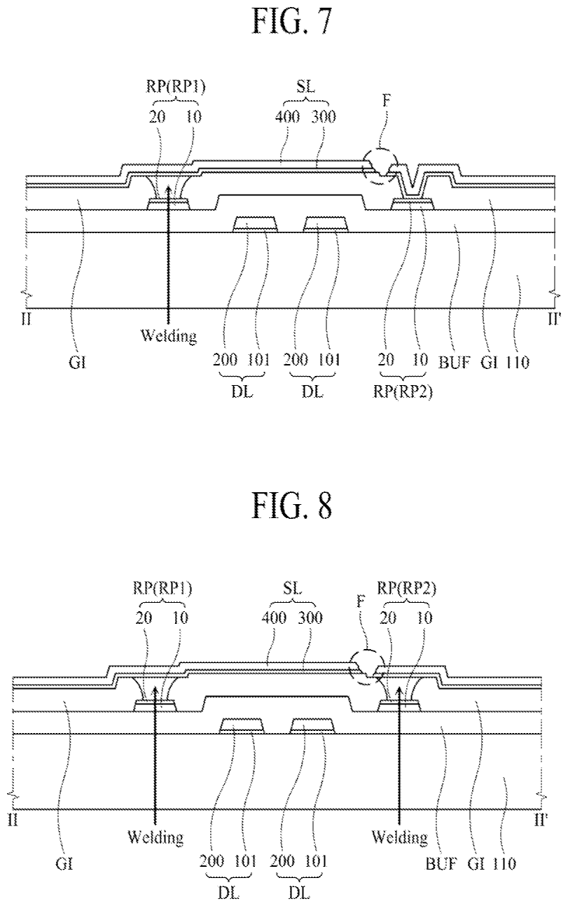

Hereinafter, referring to FIG. 7, the second aspect according to the present disclosure will be described. FIG. 7 is an enlarged cross-sectional view along cutting line II-II′ in FIG. 5, for illustrating a structure of the gate line intersecting the data line in the electroluminescence display according to the second aspect of the present disclosure.

Since the plan view is the same as that of the first aspect, refer to FIG. 5 for the planar structure. In addition, the cross-sectional view taken along III-III′ of FIG. 5 may not be necessary for understanding the structure of this aspect, so the cross-sectional view taken along III-III′ of FIG. 5 will be omitted. The structure of the gate line SL according to the second aspect may be very similar with that of the first aspect. Therefore, features with differences will be mainly described, and unnecessary redundant descriptions will not be duplicated.

The data line DL may be disposed on the substrate 110. The buffer layer BUF may be stacked on the data line DL, and may be formed as covering a surface of the substrate 110 exposed by the data line DL. The repair branch line RP may be formed on the buffer layer BUF. The repair branch line RP may be made of the same material as the semiconductor layers SA and DA and is formed on the same layer as the semiconductor layers SA and DA. The repair branch line RP may have a structure in which a semiconductor material layer 10 and a metal capping layer 20 are stacked. The repair branch line RP may have a line segment shape extending from one end portion of the gate line SL to another end portion of the gate line SL.

The gate insulating layer GI may be deposited on the repair branch line RP. The first end RP1 of the repair branch line RP may be covered by the gate insulating layer GI. The gate insulating layer GI may have a contact hole CH for exposing the second end RP2 of the repair branch line RP.

The gate line SL may be formed on the gate insulating layer GI. The gate line SL may have the structure in which a lower metal layer 300 and the upper metal layer 400 are sequentially stacked for preventing the external light reflection. The gate line SL may extend as one line segment shape, and may extend as being across the data line, but a portion corresponding to the repair branch line RP and crossing over the data line DL may be defined as the upper branch line SL1.

The upper branch line SL1 may overlap with the first end RP1 of the repair branch line RP on the gate insulating layer GI. The upper branch line SL1 may contact the second end RP2 of the repair branch line RP via the contact hole CH. As a result, the scan signal supplied through the gate line SL may be transmitted via the upper branch line SL1, but the repair branch line RP may not transmit the scan signal.

Under such a condition, when a disconnection F may occur in the upper branch line SL1, the laser irradiation may be performed on a portion overlapping with the first end RP1 of the repair branch line RP, so that the upper branch line SL1 may be electrically connected to the repair branch line RP. Accordingly, the scan signal may be supplied to the scan line SL via the repair branch line RP. In the structure according to the second aspect, the repair process using the laser irradiation may be conducted at the portions where the disconnection F may be occurred at the upper branch line SL1, so that the connection of the scan line SL may be recovered by the repair branch line RP.

### Third Aspect

Hereinafter, referring to FIG. 8, the third aspect according to the present disclosure may be explained. FIG. 8 is an enlarged cross-sectional view along cutting line II-II′ in FIG. 5, for illustrating a structure of the gate line intersecting the data line in the electroluminescence display according to the third aspect of the present disclosure.

Since the plan view is the same as that of the first aspect, refer to FIG. 5 for the planar structure. In addition, the cross-sectional view taken along III-III′ of FIG. 5 may not be necessary for understanding the structure of this aspect, so the cross-sectional view taken along III-III′ of FIG. 5 will be omitted. The structure of the gate line SL according to the third aspect may be very similar with that of the first aspect. Therefore, features with differences will be mainly described, and unnecessary redundant descriptions will not be duplicated.

The data line DL may be disposed on the substrate 110. The buffer layer BUF may be stacked on the data line DL, and may be formed as covering a surface of the substrate 110 exposed by the data line DL. The repair branch line RP may be formed on the buffer layer BUF. The repair branch line RP may be made of the same material as the semiconductor layers SA and DA and is formed on the same layer as the semiconductor layers SA and DA. The repair branch line RP may have a structure in which a semiconductor material layer 10 and a metal capping layer 20 are stacked. The repair branch line RP may have a line segment shape extending from one end portion of the gate line SL to another end portion of the gate line SL.

The gate insulating layer GI may be deposited on the repair branch line RP. The first end RP1 and the second end RP2 of the repair branch line RP may be covered by the gate insulating layer GI.

The gate line SL may be formed on the gate insulating layer GI. The gate line SL may have the structure in which a lower metal layer 300 and the upper metal layer 400 are sequentially stacked for preventing the external light reflection. The gat line SL may extend as one line segment shape, and may extend as being across the data line, but a portion corresponding to the repair branch line RP and crossing over the data line DL may be defined as the upper branch line SL1.

The upper branch line SL1 may overlap with the first end RP1 and the second end RP2 of the repair branch line RP on the gate insulating layer GI. As a result, the scan signal supplied through the gate line SL may be transmitted via the upper branch line SL1, but the repair branch line RP may not transmit the scan signal.

Under such a condition, when a disconnection F may occur in the upper branch line SL1, the laser irradiation may be performed on portions overlapping with the first end RP1 and the second end RP2 of the repair branch line RP, so that the upper branch line SL1 may be electrically connected to the repair branch line RP. Accordingly, the scan signal may not flow along the upper branch line SL1 but continues to flow to the scan line SL via the repair branch line RP. In the structure according to the third aspect, the repair process using the laser irradiation may be conducted at the portions where the disconnection F may be occurred at the upper branch line SL1, so that the connection of the scan line SL may be recovered by the repair branch line RP.

### Fourth Aspect

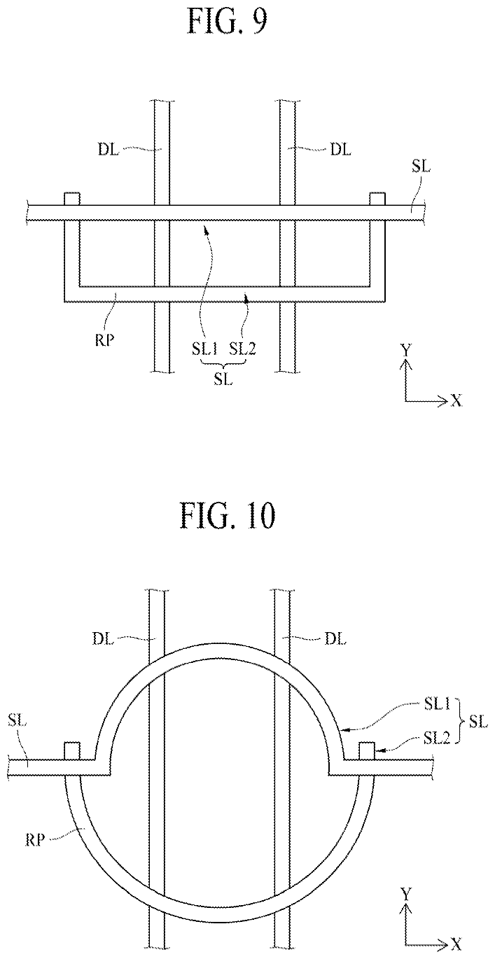

Hereinafter, referring to FIG. 9, the fourth aspect according to the present disclosure may be explained. FIG. 9 is an enlarged plan view illustrating a structure of the gate line intersecting the data line in the electroluminescence display according to the fourth aspect of the present disclosure.

As shown in FIG. 9, in the planar structure, the upper branch line SL1 and the repair branch line RP (or lower branch line SL2) may have different structure from that of the first aspect. For example, in the fourth aspect, the upper branch line SL1 may be formed as a straight line extending from the gate line SL and cross over the data line DL. Further, the repair branch line RP may bypass the upper branch line SL1 in a downward or upward direction and may have a structure of crossing the data line DL in a ‘U’ shape.

For example, the upper branch line SL1 and the repair branch line RP may have a rectangular shape in a planar structure. The upper side and the lower side of the rectangular shape may cross the data line DL. The upper side may be corresponding to the upper branch line SL1, and the lower side may be corresponding to the repair branch line RP. However, it is not limited thereto. For another example, in which there is a vertically inverted shape from FIG. 9, the repair branch line RP may be disposed as corresponding to the upper side.

The upper branch line SL1 may be disposed, so that the gate line SL may pass through a first vertex of the four vertexes of the rectangle disposed at the outer left side of the data line DL and the second vertex of the four vertexes of the rectangle disposed at the outer right side of the data line DL. At the first vertex, a first area of the upper branch line SL1 may be overlapped with the first end of the repair branch line RP (or lower branch line SL2). Further, at the second vertex, the second area of the upper branch line SL1 may be overlapped with the second end of the repair branch line RP (or, lower branch line SL2).

With respect to this structure, the line disposed at an upper layer may cross the line disposed at a lower layer, an insulating layer is between the line disposed at the upper layer and the line disposed at the lower layer, and a disconnection may occur at the portion where there is a step difference. When the disconnection is occurred, the disconnection may be recovered by welding the portion where the first area of the upper branch line SL1 is overlapped with the first end of the repair branch line RP (or, lower branch line SL2) and the other portion where the second area of the upper branch line SL1 is overlapped with the second end of the repair branch line RP (or, lower branch line SL2).

### Fifth Aspect

Hereinafter, referring to FIG. 10, the fifth aspect of the present disclosure will be described. FIG. 10 is an enlarged plan view illustrating a structure of the gate line intersecting the data line in the electroluminescence display according to the fifth aspect of the present disclosure.

As shown in FIG. 10, in the planar structure, the upper branch line SL1 and the repair branch line RP (or lower branch line SL2) may have different structure from that of the first aspect. For example, in the fifth aspect, the upper branch line SL1 and the repair branch line RP may have a circular shape or an oval shape in the planar structure. Here, the fifth aspect may be explained with a circular shape.

The upper branch line SL1 may be disposed as corresponding to a semi-circular shape spanning the first and second quadrants of the circle, or may be disposed as corresponding to the convex semi-circle shape upwards. The upper branch line SL1 may have a structure of extending from the gate line SL and crossing over the data line DL.

In addition, the repair branch line RP may be disposed as corresponding to a semi-circular shape spanning the third and fourth quadrants of the circle or as corresponding to the concave semi-circle shape downwards. The repair branch line RP may bypass the upper branch line SL1 in a downward direction and have a structure crossing the data line DL in a ‘U’ shape. However, it is not limited thereto. For another example, in which there is a vertically inverted shape from FIG. 10, the repair branch line RP may be disposed as corresponding to the upper semi-circle.

The upper branch line SL1 may be disposed so that the gate line SL may pass through the first vertex disposed at the left side of the data line DL and the second vertex disposed at the right side of the data line DL. Further, at the first vertex, the first portion of the upper branch line SL1 may be overlapped with the first end of the repair branch line RP (or, the lower branch line SL2). At the second vertex, the second portion of the upper branch line SL1 may be overlapped with the second end of the repair branch line RP (or, the lower branch line SL2).

With respect to this structure, the line disposed at an upper layer may cross the line disposed at an lower layer, an insulating layer is between the line disposed at the upper layer and the line disposed at the lower layer, and a disconnection may occur at the portion where there is a step difference. When the disconnection is occurred, the disconnection may be recovered by welding the portion where the first area of the upper branch line SL1 is overlapped with the first end of the repair branch line RP (or, lower branch line SL2) and the other portion where the second area of the upper branch line SL1 is overlapped with the second end of the repair branch line RP (or, lower branch line SL2).

The features, structures, effects and so on described in the above examples of the present disclosure are included in at least one example of the present disclosure, and are not limited to only one example. Furthermore, the features, structures, effects and the likes explained in at least one example may be implemented in a combination or modification manner with respect to other examples by those skilled in the art to which this disclosure belongs. Accordingly, the contents related to such combinations and modifications should be construed as being included in the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents. These and other changes can be made to the aspects in light of the above-detailed description. In general, in the following claims, the terms used should not be construed to limit the claims to the specific aspects disclosed in the specification and the claims, but should be construed to include all possible aspects along with the full scope of equivalents to which such claims are entitled. Accordingly, the claims are not limited by the present disclosure.

What is claimed is:

1. An electroluminescence display comprising:
a first line disposed on a substrate;
a buffer layer covering the first line;
a repair branch line disposed on the buffer layer and crossing over the first line from one side to another side of the first line;
a gate insulating layer covering the repair branch line; and
a second line disposed on the gate insulating layer and crossing over the first line,
wherein the repair branch line includes a first end disposed outside the one side of the first line and a second end disposed outside the another side of the first line,
wherein the second line includes an upper branch line being apart from the repair branch line and above the repair branch line,
wherein the first end of the repair branch line overlaps with a first area of the upper branch line, and
wherein the second end of the repair branch line overlaps with a second area of the upper branch line.

2. The electroluminescence display according to claim 1, wherein, when the upper branch line has a disconnection, the first and second ends of the repair branch line is respectively connected to the first and second areas of the upper branch line by welding.

3. The electroluminescence display according to claim 1, wherein the gate insulating layer includes a first contact hole exposing the first end of the repair branch line, and
wherein the first area of the upper branch line contacts the first end of the repair branch line via the first contact hole.

4. The electroluminescence display according to claim 3, wherein, when the upper branch line has a disconnection, the second end of the repair branch line is connected to the second area of the upper branch line by welding.

5. The electroluminescence display according to claim 3, wherein the gate insulating layer further includes a second contact hole exposing the second end of the repair branch line, and
wherein the second area of the upper branch line contacts the second end of the repair branch line via the second contact hole.

6. The electroluminescence display according to claim 1, wherein the upper branch line and the repair branch line form a hexagonal shape in a plan view,
wherein the first area of the upper branch line overlaps with the first end of the repair branch line at a first vertex of the hexagonal shape, and
wherein the second area of the upper branch line overlaps with the second end of the repair branch line at a second vertex of the hexagonal shape opposed the first vertex.

7. The electroluminescence display according to claim 1, wherein the upper branch line extends in a straight line with the second line,
wherein the upper branch line and the repair branch line form a rectangular shape in a plan view,
wherein the first area of the upper branch line overlaps with the first end of the repair branch line at a first vertex of the rectangular shape, and
wherein the second area of the upper branch line overlaps with the second end of the repair branch line at a second vertex of the rectangular shape opposed the first vertex.

8. The electroluminescence display according to claim 1, wherein the upper branch line and the repair branch line form a circular shape in a plan view,
wherein the upper branch line has a convex semi-circular shape,
wherein the repair branch line has a concave semi-circular shape,
wherein the first area of the upper branch line overlaps with the first end of the repair branch line at a first intersection where the convex semi-circular shape and the concave semi-circular shape intersect, and
wherein the second area of the upper branch line overlaps with the second end of the repair branch line at a second intersection where the convex semi-circular shape and the concave semi-circular shape intersect.

9. The electroluminescence display according to claim 1, wherein the first line includes a data line and a driving current line, and the second line includes a gate line, and

10. The electroluminescence display according to claim 9, further comprising:
a switching thin film transistor connected to the gate line and the data line;
a driving thin film transistor connected to the switching thin film transistor and the driving current line;
a planarization layer covering the switching thin film transistor and the driving thin film transistor above the substrate; and
a light emitting element on the planarization layer and connected to the driving thin film transistor.

11. A method for manufacturing an electroluminescence display comprising:
forming a first line on a substrate;
depositing a buffer layer covering the first line;
forming a repair branch line on the buffer layer and crossing over the first line from one side to another side;
depositing a gate insulating layer covering the repair branch line on the substrate; and
forming a second line on the gate insulating layer crossing over the first line,
wherein the repair branch line includes a first end disposed outside the one side of the first line and a second end disposed outside the another side of the first line,
wherein the second line includes an upper branch line being apart from the repair branch line and above the repair branch line,
wherein the first end of the repair branch line overlaps with a first area of the upper branch line, and
wherein the second end of the repair branch line overlaps with a second area of the upper branch line.

12. The method for manufacturing the electroluminescence display according to claim 11, further comprising:
inspecting an electrical disconnection at the upper branch line; and
repairing the electrical disconnection by welding the first end of the repair branch line with the first area of the upper branch line, and welding the second end of the repair branch line with the second area of the upper branch line, when the upper branch line has the electrical disconnection.

13. The method for manufacturing the electroluminescence display according to claim 11, wherein the depositing the gate insulating layer includes forming a first contact hole exposing the first end of the repair branch line, and
wherein, in the forming the second line, the first area of the upper branch line contacts the first end of the repair branch line via the first contact hole.

14. The method for manufacturing the electroluminescence display according to claim 13, further comprising:
inspecting an electrical disconnection at the upper branch line; and
repairing the electrical disconnection by welding the second end of the repair branch line with the second area of the upper branch line, when the upper branch line has the electrical disconnection.

15. The method for manufacturing the electroluminescence display according to claim 11, wherein the depositing the gate insulating layer further includes forming a second contact hole exposing the second end of the repair branch line, and
wherein, in the forming the second line, the second area of the upper branch line contacts the second end of the repair branch line via the second contact hole.

16. An electroluminescence display comprising:
a data line disposed on a substrate;
a buffer layer covering the data line;
a repair branch line disposed on the buffer layer and crossing over the data line;
a gate insulating layer covering the repair branch line; and
a gate line disposed on the gate insulating layer and having a non-overlapping portion with the repair branch line between first and second overlapping areas where the repair branch line overlaps with the gate line.

17. The electroluminescence display according to claim 16, wherein, when the upper branch line has a disconnection, the repair branch line is welded with the gate line in at least one of the first and second overlapping areas.

18. The electroluminescence display according to claim 16, wherein the gate insulating layer includes at least one of first and second contact holes exposing the repair branch line, and the gate line contacts the repair branch line via the at least one of first and second contact holes.

19. The electroluminescence display according to claim 16, wherein the non-overlapping portion of the gate line and the repair branch line form a hexagonal shape in a plan view.

20. The electroluminescence display according to claim 16, wherein the non-overlapping portion of the gate line and the repair branch line form a circular shape in a plan view, and
wherein the non-overlapping portion has a convex semi-circular shape, and the repair branch line has a concave semi-circular shape.
